(19) United States
(12) Patent Application Publication
(10) Pub. No.: US 2007/0013081 A1
(43) Pub. Date: Jan. 18, 2007

(54) ELECTRONIC MODULE WITH STACKED IC CHIP STRUCTURE

(75) Inventor: YONG BUM LEE, KYUNGKI-DO (KR)

Correspondence Address: LOWE HAUPTMAN BERNER, LLP, 1700 DIAGONAL ROAD, SUITE 300, ALEXANDRIA, VA, 22314, US

(73) Assignee: SAMSUNG ELECTRO-MECHANICS CO., LTD., KYUNGKI-DO (KR)

(21) Appl. No.: 11/457,060

(22) Filed: Jul. 12, 2006

(30) Foreign Application Priority Data
Jul. 14, 2005 (KR) 10-2005-63700

(51) Int. Cl. H01L 23/52

(52) U.S. Cl. 257/777

(57) ABSTRACT

The invention relates to an electronic module with a plurality of IC chips staked densely. The electronic module includes a substrate with an electrode formed thereon and at least one spacer disposed on the substrate. The electronic module also includes an IC chip disposed on the spacer and electrically connected to the substrate. The IC chip has a size larger than the spacer. The substrate and the IC chip forms a space therebetween. The invention miniaturizes and minimizes circuit connections and configurations between the IC chips and chip components to minimize electric resistance and inductance, thereby enhancing product capabilities. Also, the invention achieves miniaturization and integration of mobile products such as mobile phones to improve product competitiveness.

### CLAIM OF PRIORITY

This application claims the benefit of Korean Patent Application No. 2005-63700 filed on Jul. 14, 2005, in the Korean Intellectual Property Office, the disclosure of which is incorporated herein by reference.

### BACKGROUND OF THE INVENTION

1. Field of the Invention

The present invention relates to an electronic module having a plurality of integrated circuit chips (hereinafter, referred to as IC chip) densely stacked. More particularly, the invention relates to an electronic module having an improved IC chip stacked structure in which a plurality of IC chips and chip components are efficiently stacked to achieve miniaturization and integration, enhancing performance of an electronic product, thereby maximizing space utilization and achieving miniaturization of a final product.

2. Description of the Related Art

With recent rapid advancement in electronic industry, electronic products are becoming more miniaturized and multi-functional to meet the needs of the users.

As an assembly technology of electronic devices in response to such needs, there have been developed a technology to assemble a single or different types of IC chips into one single unit module.

Since the technology assembles individual IC chips into one module, it is advantageous in terms of size, weight and area for mounting components compared with assembling individual IC chips into different modules.

Such a module technology is extensively applied to mobile phones, and the like that requires miniaturization and light weight to reduce the area for mounting components and achieve light weight thereof.

In general, as an approach to assemble bare chips or flip chips of a plurality of semiconductor elements or IC chips into one module, they can be stacked one on top of another or aligned in parallel. The former stacks the chips and thus complicates the process in a limited thickness. The latter arranges at least two IC chips in parallel on the same plane, which is difficult to reduce the size to achieve miniaturization. In general, IC chips are usually stacked in a module to achieve miniaturization and light weight.

A conventional electronic module having such a stacked IC chip structure is described as follows.

FIG. 1 is a sectional view illustrating an example of a conventional electronic module 200. In this electronic module 200, a first IC chip 212 is mounted on a substrate 210 and a first spacer 214 is disposed on the first IC chip 212. A second spacer 216 is disposed on the substrate 210 in a predetermined distance from the first IC chip 212. And a second IC chip 220 is disposed on the first spacer 214 placed on the first IC chip 212 and on the second spacer 216. The first IC chip 212 and the second IC chip 220 are electrically connected, respectively, to the substrate 210 by a plurality of bonding wires 222.

Through the above described arrangement, the plurality of first IC chips 212 and second IC chips 220 form a stacked structure of the conventional electronic module 200.

However, in such a conventional electronic module 200, chip components other than the first IC chip 212 and the second IC chip 220, for example, basic elements such as a resistor, MLCC, inductor, and the like are also be mounted on the substrate 210 but on separate locations. Therefore, the conventional electronic module 200 is not effectively miniaturized and thus requires structural improvements.

FIG. 2 illustrates another electronic module 250 having a stacked IC chip structure according to the prior art.

This electronic module 250 is a single unit package with a plurality of IC chips assembled therein. The module 250 includes a substrate 256 with first bonding pads 252 formed around a chip mounting area thereof and second bonding pads 254 formed thereon in a predetermined distance from the first bonding pads 254. The electronic module 250 also includes a first chip 260 mounted on the chip mounting area, a spacer 262 having a thickness larger than a height of the first chip 260, disposed between the second bonding pads 254 and the first chip 260, and a second chip 264, which is larger than the first chip 260, having chip pads 264a on upper surfaces of peripheral portions thereof that are attached to an upper surface of the spacer 262.

In addition, the electronic module 250 includes bonding wires 270 electrically connecting the chip pads 260a of the first chip 260 with the corresponding first bonding pads 252, exterior terminals 274 attached on a surface of the substrate 256 opposite of a chip mounting surface thereof, and a package body 280 that encapsulates the first chip 260, the second chip 264, the bonding wires 270 and the spacer 262.

However, such a conventional structure does not take account of other chip components besides the first chip 260 and the second chip 264 which should be mounted separately, and thus there is a need for structural improvement.

FIG. 3 illustrates another conventional electronic module 300. In this conventional structure, a first semiconductor element 312 is disposed on a substrate 310 with an electrode (not shown) formed thereon, and second and third semiconductor elements 314 and 316 are stacked above the first semiconductor element 312 with adhesive layers (spacers) 314a and 316a disposed alternately therewith. The first, second and third semiconductor elements 312, 314 and 316 are connected, respectively, to the substrate 310 by bonding wires 320.

Although the first, second and third semiconductor elements 312, 314 and 316 are effectively stacked in this conventional technology, other chip components are not taken into account and thus should be mounted separately. Therefore, there also is a need for structural improvement.

### SUMMARY OF THE INVENTION

The present invention has been made to solve the foregoing problems of the prior art and therefore an object of certain embodiments of the present invention is to provide an electronic module having an improved stacked IC chip structure, which maximizes utilization of space for mounting chip components in a stacked IC chip structure to minimize connections among the IC chips and chip components and the size of the circuits, thereby enhancing performance characteristics of the IC chips and chip components.

Another object of certain embodiments of the invention is to provide an electronic module having an improved stacked IC chip structure, which maximizes space utilization in the stacked IC chip structure to achieve miniaturization and integration of a final product, thereby enhancing competitiveness of the product.

According to an aspect of the invention for realizing the object, there is provided an electronic module having a stacked integrated circuit chip structure, including: a substrate with an electrode formed thereon; at least one spacer disposed on the substrate; and an integrated circuit chip disposed above the spacer and is electrically connected to the substrate, the integrated circuit chip having a size larger than the spacer, wherein the substrate and the integrated circuit chip form a space therebetween.

Preferably, the space forms an area for mounting chip components on the substrate.

Preferably, the electronic module having a stacked integrated circuit chip structure further includes a second integrated circuit chip and a second spacer disposed in the space.

Preferably, the second spacer and the second integrated circuit chip stacked on the second spacer form a height the same as that of the at least one spacer.

Preferably, the integrated circuit chip and the second integrated chip are bare chips.

Preferably, the integrated circuit chip is a bare chip and the second integrated circuit chip is a flip chip.

According to another aspect of the invention for realizing the object, there is provided an electronic module having a stacked integrated circuit chip structure, including: a substrate with an electrode formed thereon; a first integrated circuit chip disposed on the substrate; a plurality of spacers disposed on the first integrated circuit chip or the substrate; and a second integrated circuit chip which has a size larger than the first integrated circuit chip and is disposed on the plurality of spacers, wherein the substrate and the second integrated circuit chip form a space therebetween for mounting chip components.

Preferably, the first and second integrated circuit chips are bare chips.

Preferably, the first integrated circuit chip is a flip chip and the second integrated circuit chip is a bare chip.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a configuration view illustrating an electronic module having a stacked IC chip structure according to the prior art, in which (a) is a plan view and (b) is a sectional view;

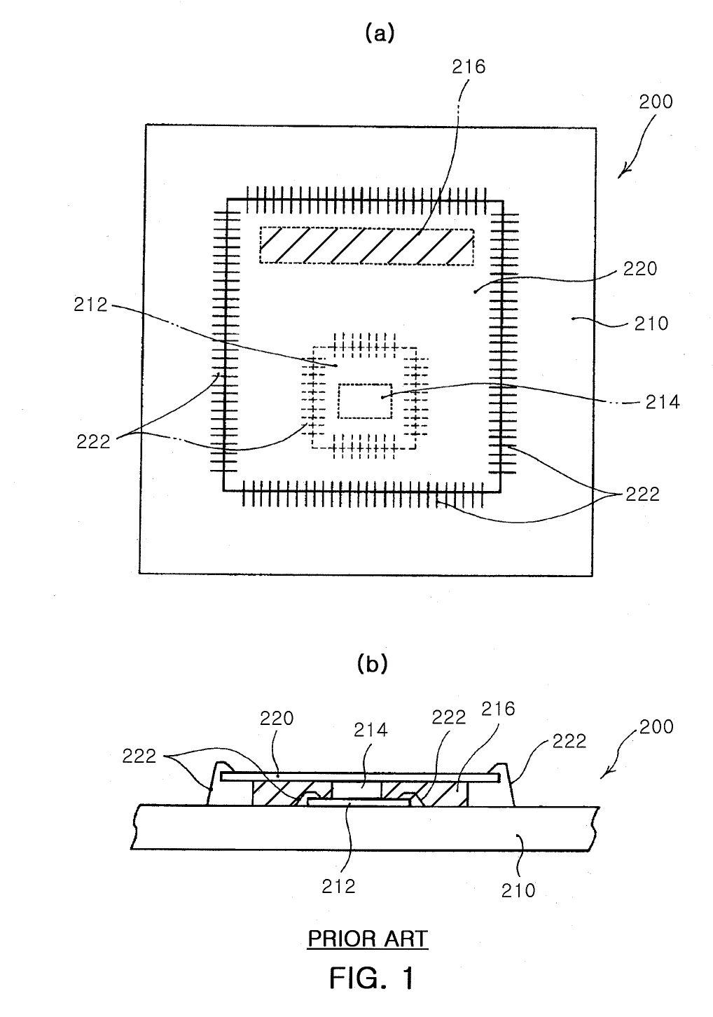

FIG. 2 is a configuration view illustrating another electronic module having a stacked IC chip structure according to the prior art, in which (a) is a plan view and (b) is a sectional view;

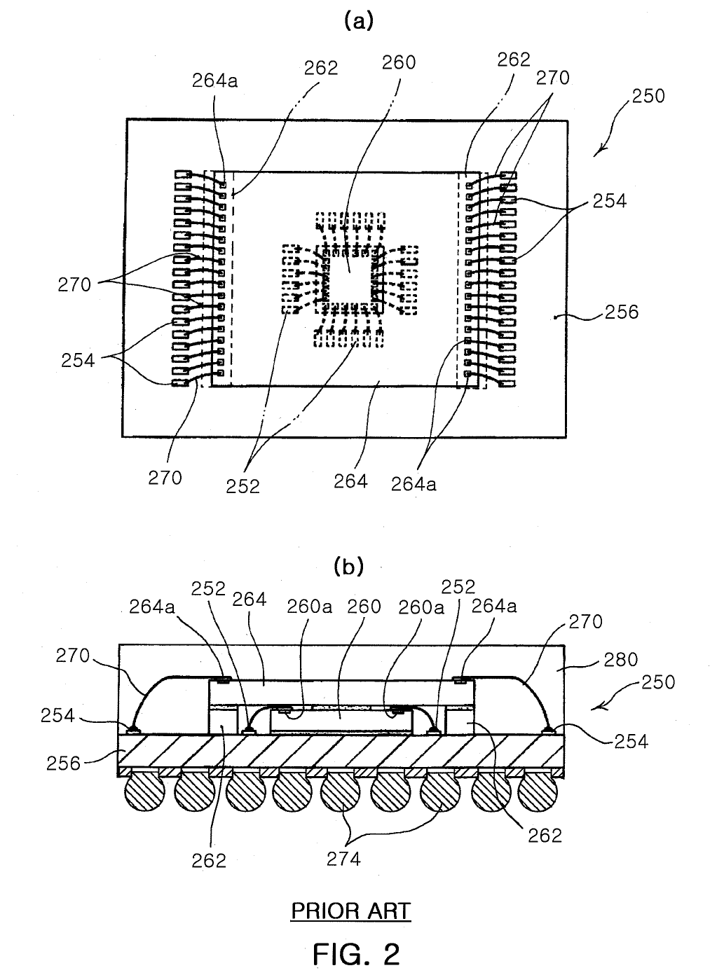

FIG. 3 is a configuration view illustrating further another electronic module having a stacked IC chip structure according to the prior art, in which (a) is a plan view and (b) is a sectional view;

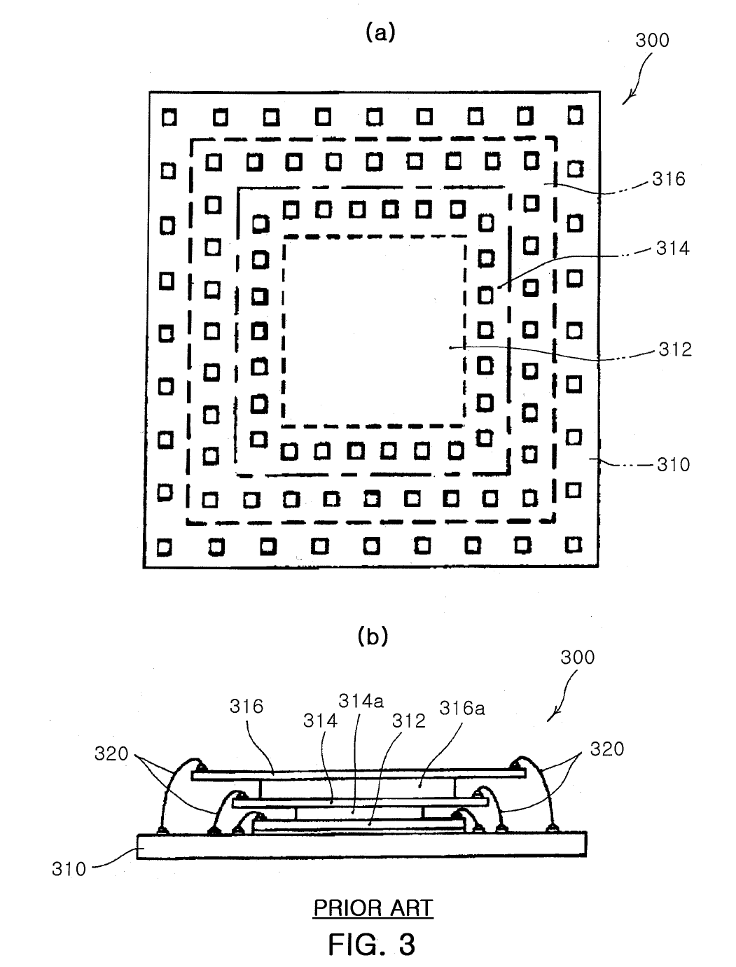

FIG. 4 is a configuration view illustrating an electronic module having a stacked IC chip structure according to an embodiment of the present invention, in which (a) is a plan view and (b) is a sectional view;

FIG. 5 is a configuration view illustrating an electronic module having a stacked IC chip structure according to another embodiment of the present invention, in which (a) is a plan view and (b) is a sectional view;

FIG. 6 is a configuration view illustrating an electronic module having a stacked IC chip structure according to further another embodiment of the present invention, in which (a) is a plan view and (b) is a sectional view; and

FIG. 7 is a configuration view illustrating an electronic module having a stacked IC chip structure according to yet another embodiment of the present invention, in which (a) is a plan view and (b) is a sectional view.

### DETAILED DESCRIPTION OF THE PREFERRED EMBODIMENT

Preferred embodiments of the present invention will now be described in detail with reference to the accompanying drawings.

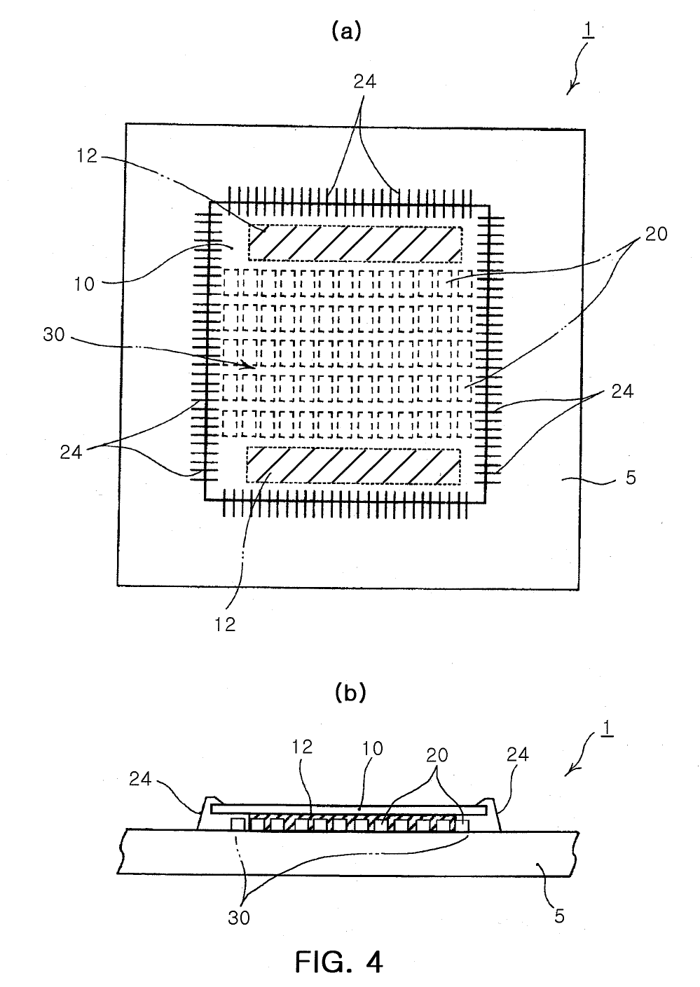

As shown in FIG. 4, an electronic module 1 having a stacked IC chip structure according to an embodiment of the invention has an IC chip densely stacked above chip components 20 that are mounted integrally.

The electronic module 1 having a stacked IC chip structure according to the present invention has a substrate 5 with electrodes (not shown) formed thereon. And at least one spacer 12 is disposed on the substrate 5. The spacer 12 is made of insulator of various materials and formed to have various properties. It can be formed in advance to have a predetermined shape and attached to the substrate 5.

In addition, the electronic module 1 includes the IC chip 10 having a size larger than the spacer 12, disposed above the spacer 12 and electrically connected to the substrate 5.

The IC chip 10 and the substrate 5 are electrically connected to each other with gold bumps formed on chip pads (not shown) of the IC chip 10 connected to corresponding bonding pads (not shown) by a plurality of bonding wires 24.

In addition, the substrate 5 and the IC chip 10 form a space 30 therebetween for mounting chip components. That is, the IC chip 10 is supported by the spacer 12 to be disposed above the substrate 5, thereby forming the space 30 between the IC chip 10 and a surface of the substrate 5. The space 30 is partially occupied by the spacer 12, thereby forming the rest of vacant areas on the substrate 5 for mounting the chip components 20.

In order for the above, once the size of the spacer 12 and the sizes of the IC chips are set beforehand, the size of the space 30 can be planned in advance accordingly.

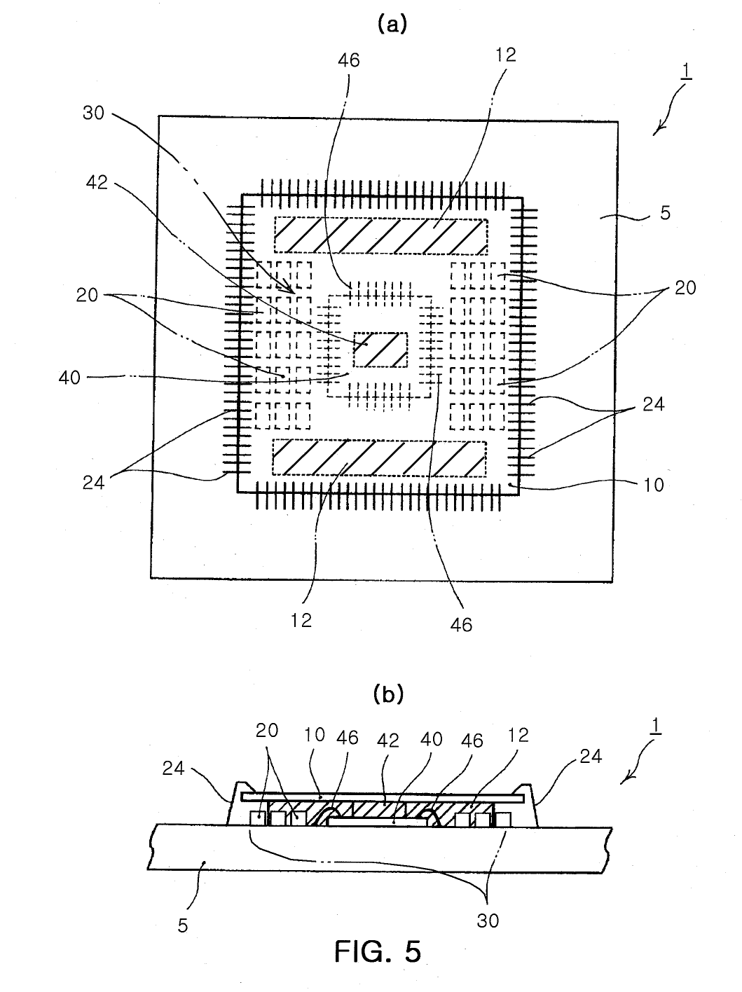

Preferably, as shown in FIG. 5, a second IC chip 40 and a second spacer 42 can be disposed with the chip components 20 in the space 30. In this case, the dimensions of the space 30 can be determined in advance in consideration of the sizes of the second IC chip 40 and the second spacer 42. The second spacer 42 and the second IC chip 40 stacked on the second spacer 42 form a height the same as the at least one spacer 12 to support the IC chip 10.

In this case, the second spacer 42 is also made of insulation material.

In the case of mounting the second IC chip 40 and the second spacer 42 as described above, the second IC chip 40 and the second spacer 42 are smaller than the IC chip 10 disposed above. During the assembly with the substrate 5, the smaller-sized second IC chip 40 is connected to the substrate 5 by bonding wires 46 prior to connecting the larger-sized IC chip 10 to the substrate 5 by bonding wires 24.

Preferably, the IC chip 10 and the second IC chip 40 can be bare chips. Also, preferably, the IC chip 10 can be a bare chip and the second IC chip 40 can be a flip chip.

The bare chip refers to a chip that is not housed in a package, but cut out from a wafer. Using bare chips can be advantageous in reducing the costs whereas using flip chips can be advantageous in terms of performance.

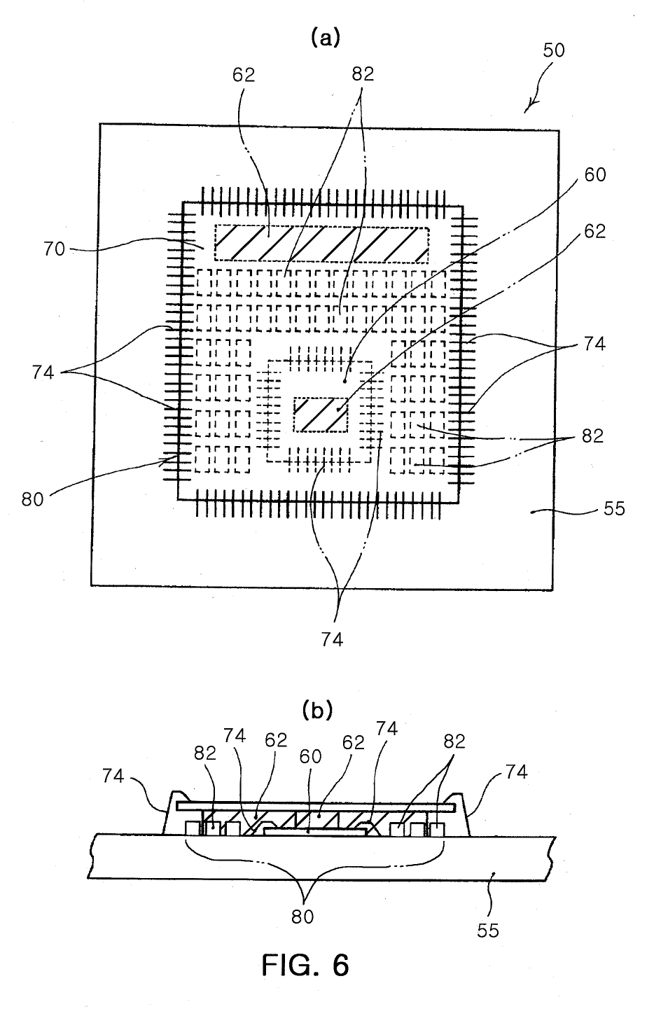

According to another embodiment of the invention, a different structure is presented in FIG. 6.

According to this embodiment, the electronic module 50 having a stacked IC chip structure is provided with a substrate 55 having electrodes (not shown) formed thereon.

The electronic module 50 also includes a first IC chip 60 disposed on the substrate 55 and a plurality of spacers 62 disposed on the first IC chip 60 and on the substrate 55. The spacers 62 are made of insulator of various materials. Depending on the size of the first IC chip 60 or a second IC chip 70 explained later, the spacer 62 is formed in advance to have a predetermined shape and size and attached to the first IC chip 60 or the substrate 55.

In addition, the present invention includes a second IC chip 70 disposed on the spacers 62, having a size larger than the first IC chip 60.

The first and second IC chips 60 and 70 are electrically connected to the substrate 55 at a plurality of locations by bonding wires 74.

When the first and second IC chips 60 and 70 are disposed on the substrate 55 as described above, the substrate 55 and the second IC chip 70 forms therebetween a space 80 for mounting chip components.

Therefore, the space 80 for mounting chip components forms an area where a plurality of chip components of basic elements such as a resistor, MLCC, inductor, and the like are mounted.

Preferably, the first and second IC chips 60 and 70 can be bare chips. The bare chip refers to a chip which is not housed in a package, but cut out from a wafer. Using the bare chips is advantageous in terms of cost reduction. The first and second IC chips 60 and 70 are electrically connected to the substrate 55 at a plurality of locations by the bonding wires 74.

Also, preferably, the first IC chip 60′ can be a flip chip, and the second IC chip 70 can be a bare chip.

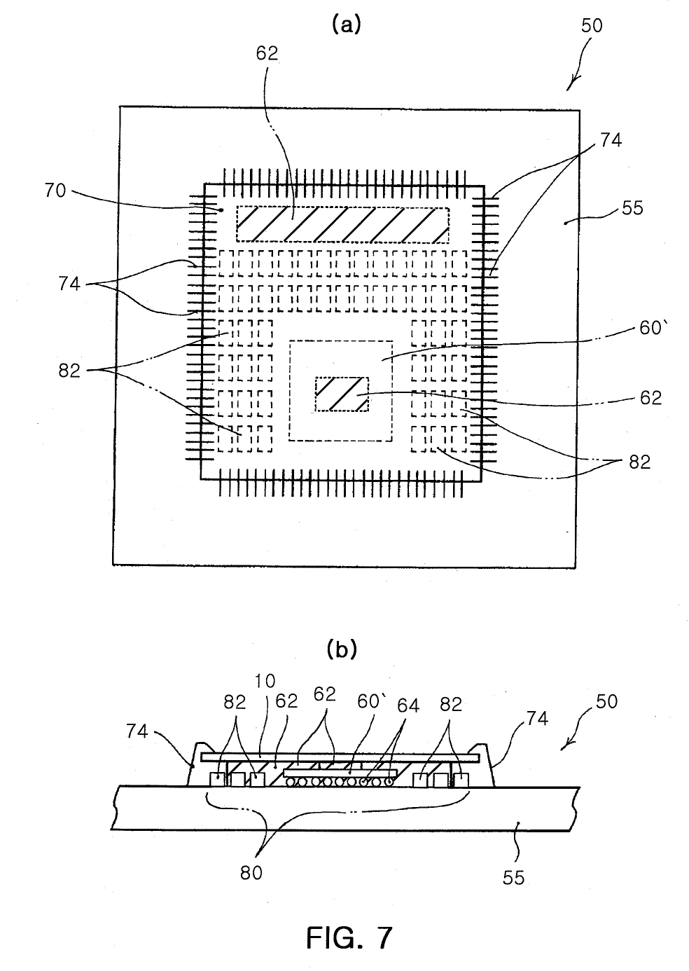

In this case, as shown in FIG. 7, when the first IC chip 60′ is a flip chip, it is electrically connected to the substrate 55 using solder balls 64 and bumps, and thus inductance and resistance can be significantly reduced compared with wire connection. Also, structurally, as power is supplied directly from the substrate 55, voltage fluctuation is reduced compared with bare chip connection structure.

In addition, the second IC chip 70 is electrically connected to the substrate 55 by the bonding wires 74.

In the above described structure, the bonding wires are not necessary for the first IC chip 60′, and the substrate 55 and the second IC chip 70 forms therebetween a greater space 80 for mounting chip components. Therefore, greater number of chip components 82 can be mounted in the space 80.

According to certain embodiments of the invention as set forth above, in a stacked arrangement of the IC chips, circuit connections and configurations can be miniaturized and minimized to reduce electric resistance and inductance generated among IC chips, chip components and a substrate, thereby enhancing technological capabilities of a product.

Further, the invention maximizes utilization of space between the IC chips and the chip components to achieve miniaturization and integration of a final product that adopts the invention, namely, mobile products such as mobile phones, thereby enhancing competitiveness thereof.

The present invention has been shown and described in connection with the preferred embodiments, but the invention may be embodied in many different forms and should not be construed as limited to the embodiments set forth herein. It will be apparent to those skilled in the art that modifications and variations can be made without departing from the spirit and scope of the invention as defined by the appended claims.

What is claimed is:

1. An electronic module having a stacked integrated circuit chip structure, comprising:
a substrate with an electrode formed thereon;
at least one spacer disposed on the substrate; and
an integrated circuit chip disposed above the spacer and is electrically connected to the substrate, the integrated circuit chip having a size larger than the spacer,
wherein the substrate and the integrated circuit chip form a space therebetween.

2. The electronic module having a stacked integrated circuit chip structure according to claim 1, wherein the space forms an area for mounting chip components on the substrate.

3. The electronic module having a stacked integrated circuit chip structure according to claim 1, further comprising a second integrated circuit chip and a second spacer disposed in the space.

4. The electronic module having a stacked integrated circuit chip structure according to claim 3, wherein the second spacer and the second integrated circuit chip stacked on the second spacer form a height the same as that of the at least one spacer.

5. The electronic module having a stacked integrated circuit chip structure according to claim 4, wherein the integrated circuit chip and the second integrated chip are bare chips.

6. The electronic module having a stacked integrated circuit chip structure according to claim 4, wherein the integrated circuit chip is a bare chip and the second integrated circuit chip is a flip chip.

7. An electronic module having a stacked integrated circuit chip structure, comprising:
a substrate with an electrode formed thereon;
a first integrated circuit chip disposed on the substrate;
a plurality of spacers disposed on the first integrated circuit chip or the substrate; and
a second integrated circuit chip which has a size larger than the first integrated circuit chip and is disposed on the plurality of spacers,
wherein the substrate and the second integrated circuit chip form a space therebetween for mounting chip components.

8. The electronic module having a stacked integrated circuit chip structure according to claim 7, wherein the first and second integrated circuit chips are bare chips.

9. The electronic module having a stacked integrated circuit chip structure according to claim 7, wherein the first integrated circuit chip is a flip chip and the second integrated circuit chip is a bare chip.
